(19) United States
(12) Patent Application Publication
(10) Pub. No.: US 2026/0322234 A1
(43) Pub. Date: Oct. 15, 2026

(54) INDUCTIVE CURRENT DETECTION CIRCUIT FOR DC-DC CONVERTER, DC-DC CONVERTER AND CHIP

(71) Applicant: SG MICRO CORP, Beijing (CN)

(72) Inventors: Lei TAN, Beijing (CN); Hongyu CHENG, Beijing (CN)

(73) Assignee: SG MICRO CORP, Beijing (CN)

(21) Appl. No.: 18/880,294

(22) PCT Filed: Jun. 24, 2024
(86) PCT No.: PCT/CN2024/101054

§ 371 Date: Dec. 31, 2024

(30) Foreign Application Priority Data
Nov. 24, 2023 (CN) 202311586067.3

(51) Int. Cl. H02M 1/00; G01R 19/14; H02M 3/158

(52) U.S. Cl. CPC H02M 1/0009; G01R 19/14; H02M 3/158

(57) ABSTRACT

An inductive current detection circuit for a Direct Current (DC)-DC converter, the DC-DC converter, and a chip are provided. The inductive current detection circuit includes a switching circuit, a first control circuit, a second control circuit, and an output circuit. The switching circuit transfers a voltage at a first end of an inductor of the DC-DC converter to a first node during the period when a first control signal is at an active level. The first control circuit generates a voltage difference equal to a first increment value between a second node and the first node. The second control circuit records a historical voltage positively correlated with a voltage of the first node during the period when a second control signal is at the active level, and generate a voltage difference equal to a second increment value between the second node and the first node according to the historical voltage.

### CROSS-REFERENCE TO THE RELATED APPLICATIONS

This application is the national phase entry of International Application No. PCT/CN2024/101054, filed on Jun. 24, 2024, which is based upon and claims priority to Chinese Patent Application No. 202311586067.3, filed on Nov. 24, 2023, the entire contents of which are incorporated herein by reference.

### TECHNICAL FIELD

The present disclosure relates to the technical field of integrated circuits, and in particular, to an inductive current detection circuit for a Direct Current (DC)-DC converter, the DC-DC converter, and a chip.

### BACKGROUND

DC-DC converters are widely used as power supplies for various electronic devices due to the advantages of high efficiency and low power consumption. Taking a synchronous buck converter (BUCK) as an example, when a load current drops below an inductive current, the inductive current backflow phenomenon may occur under light load conditions. Excessive reverse current may draw energy from an output energy storage capacitor of BUCK, causing a negative voltage at an output end of BUCK, thereby damaging the load. In order to avoid repeated transfer of energy between an input power supply and an output voltage, it is necessary to turn off a freewheeling tube of BUCK in time when it is detected that the inductive current is close to zero, so as to reduce the power consumption of BUCK in a light load mode. Therefore, it is expected to accurately detect the inductive current of the DC-DC converter.

### SUMMARY

Embodiments described in the present disclosure provide an inductive current detection circuit for a DC-DC converter, the DC-DC converter, and a chip.

According to a first aspect of the present disclosure, an inductive current detection circuit for a DC-DC converter is provided. The inductive current detection circuit includes a switching circuit, a first control circuit, a second control circuit, and an output circuit. The switching circuit is configured to transfer a voltage at a first end of an inductor of the DC-DC converter to a first node during the period when a first control signal is at an active level. A first end of the inductor is directly coupled to a second electrode of a freewheeling tube of the DC-DC converter. The first control signal is at the active level during the freewheeling period when the freewheeling tube is turned on and within the dead time immediately after the freewheeling period. The first control circuit is configured to generate a voltage difference equal to a first increment value between the second node and the first node. The second control circuit is configured to record a historical voltage positively correlated with a voltage of the first node during the period when the second control signal is at the active level, and generate a voltage difference equal to a second increment value between the second node and the first node according to the historical voltage, so that the voltage difference between the second node and the first node is equal to the sum of the first increment value and the second increment value. The second control signal is at the active level within the dead time. The output circuit is configured to generate a reverse current detection signal according to a voltage of the second node and output the reverse current detection signal from a signal output end of the inductive current detection circuit. When the voltage of the second node rises to an inversion threshold, the reverse current detection signal is inverted to the active level for turning off the freewheeling tube.

In some embodiments of the present disclosure, the active level of the reverse current detection signal is a high level. The output circuit includes a first constant current source, a first transistor, and an inverter. The first constant current source is configured to output a first constant current. A control electrode of the first transistor is coupled to the second node. A first electrode of the first transistor is coupled to a first electrode of the freewheeling tube. A second electrode of the first transistor is coupled to an output end of the first constant current source and an input end of the inverter. An output end of the inverter is coupled to the signal output end.

In some embodiments of the present disclosure, the active level of the reverse current detection signal is a low level. The output circuit includes a first constant current source and a first transistor. The first constant current source is configured to output a first constant current. A control electrode of the first transistor is coupled to the second node. A first electrode of the first transistor is coupled to a first electrode of the freewheeling tube. A second electrode of the first transistor is coupled to an output end of the first constant current source and the signal output end.

In some embodiments of the present disclosure, the first control circuit includes a second constant current source and a second transistor. The second constant current source is configured to output a second constant current. The second constant current is less than the first constant current. A control electrode and a second electrode of the second transistor are coupled to the second node and an output end of the second constant current source. A first electrode of the second transistor is coupled to the first node.

In some embodiments of the present disclosure, the size of the second transistor is the same as that of the first transistor.

In some embodiments of the present disclosure, the first control circuit includes a second constant current source and a diode. The second constant current source is configured to output a second constant current. The second constant current is less than the first constant current. An anode of the diode is coupled to the second node and an output end of the second constant current source. A cathode of the diode is coupled to the first node.

In some embodiments of the present disclosure, a threshold voltage of the diode is equal to a threshold voltage of the first transistor.

In some embodiments of the present disclosure, the second control circuit includes a first switch, a third transistor, and a capacitor. A controlled end of the first switch is provided with the second control signal. A first end of the first switch is coupled to the first node. A second end of the first switch is coupled to a first end of the capacitor and a control electrode of the third transistor. A second end of the capacitor is coupled to a first electrode of the first transistor. A first electrode of the third transistor is coupled to the second node. A second electrode of the third transistor is coupled to a first voltage end.

In some embodiments of the present disclosure, the first switch is a fourth transistor. A control electrode of the fourth transistor is provided with the second control signal. A first electrode of the fourth transistor is coupled to the first end of the capacitor and the control electrode of the third transistor. A second electrode of the fourth transistor is coupled to the first node.

In some embodiments of the present disclosure, the switching circuit includes a second switch. A controlled end of the second switch is provided with the first control signal. A first end of the second switch is coupled to the first node. A second end of the second switch is coupled to the first end of the inductor of the DC-DC converter and the second electrode of the freewheeling tube.

In some embodiments of the present disclosure, the DC-DC converter operates in a Discontinuous Conduction Mode (DCM).

In some embodiments of the present disclosure, a first end of the switching circuit is coupled to the first end of the inductor and the second electrode of the freewheeling tube, and a second end of the switching circuit is coupled to a first end of the first control circuit and a first end of the second control circuit through the first node. A second end of the first control circuit is coupled to an input end of the output circuit and a second end of the second control circuit through the second node. An output end of the output circuit serves as the signal output end of the inductive current detection circuit.

In some embodiments of the present disclosure, the first control signal is generated according to an upper tube control signal and a lower tube control signal, and the first control signal is at the active level within a time period from when the lower tube control signal is inverted to the active level to when the upper tube control signal is inverted to the active level.

In some embodiments of the present disclosure, the second control signal is generated according to the upper tube control signal and the lower tube control signal, and the second control signal is at the active level within a time period from when the lower tube control signal is inverted to an inactive level to when the upper tube control signal is inverted to the active level. According to a second aspect of the present disclosure, an inductive current detection circuit for a DC-DC converter is provided. The inductive current detection circuit includes a first transistor, a second transistor, a third transistor, a first constant current source, a second constant current source, a capacitor, a first switch, a second switch, and an inverter. The first constant current source is configured to output a first constant current. A control electrode of the first transistor is coupled to a control electrode and a second electrode of the second transistor. A first electrode of the first transistor is coupled to a first electrode of a freewheeling tube of the DC-DC converter. A second electrode of the first transistor is coupled to an output end of the first constant current source and an input end of the inverter. An output end of the inverter is coupled to a signal output end of the inductive current detection circuit. A reverse current detection signal is output from the signal output end. An active level of the reverse current detection signal is configured to turn off the freewheeling tube. The second constant current source is configured to output a second constant current. The second constant current is less than the first constant current. The control electrode of the second transistor is coupled to an output end of the second constant current source and a first electrode of the third transistor. A first electrode of the second transistor is coupled to a first end of the first switch and a first end of the second switch. A controlled end of the second switch is provided with a first control signal. A second end of the second switch is coupled to a first end of an inductor of the DC-DC converter and a second electrode of the freewheeling tube. The first control signal is at the active level during the freewheeling period when the freewheeling tube is turned on and within the dead time immediately after the freewheeling period. A controlled end of the first switch is provided with a second control signal. A second end of the first switch is coupled to a first end of the capacitor and a control electrode of the third transistor. The second control signal is at the active level within the dead time. A second end of the capacitor is coupled to the first electrode of the first transistor. A second electrode of the third transistor is coupled to a first voltage end.

According to a third aspect of the present disclosure, a DC-DC converter is provided. The DC-DC converter includes the inductive current detection circuit according to the first aspect or the second aspect of the present disclosure.

According to a fourth aspect of the present disclosure, a chip is provided. The chip includes the DC-DC converter according to the third aspect of the present disclosure.

According to a fifth aspect of the present disclosure, an electronic device is provided. The electronic device includes the chip according to the fourth aspect of the present disclosure.

### BRIEF DESCRIPTION OF THE DRAWINGS

In order to more clearly illustrate the present disclosure or the technical solutions in the related art, the drawings used in the description of the embodiments or the related art will be briefly described below. It is apparent that the drawings described below are only some embodiments of the present disclosure and not intended to limit the present disclosure. Other drawings may further be obtained by those of ordinary skill in the art according to these drawings without creative efforts.

FIG. 1 is an exemplary topological diagram of a DC-DC converter.

FIG. 2 is a waveform diagram of some signals of a DC-DC converter shown in FIG. 1 in the absence of a reverse current.

FIG. 3 is a waveform diagram of some signals of a DC-DC converter shown in FIG. 1 in the presence of a reverse current.

FIG. 4 is a schematic block diagram of an inductive current detection circuit for a DC-DC converter according to an embodiment of the present disclosure.

FIG. 5 is an exemplary circuit diagram of an inductive current detection circuit for a DC-DC converter according to an embodiment of the present disclosure.

FIG. 6 is another exemplary circuit diagram of an inductive current detection circuit for a DC-DC converter according to an embodiment of the present disclosure.

In the drawings, reference signs with the same last two digits correspond to the same elements. It is to be noted that the elements in the drawings are schematic and not drawn to scale.

### DETAILED DESCRIPTION OF THE EMBODIMENTS

In order to make the purpose, technical solutions, and advantages of the embodiments of the present disclosure clearer, the technical solutions in the embodiments of the present disclosure will be described clearly and completely below with reference to the drawings. It is apparent that the described embodiments are part rather than all embodiments of the present disclosure. On the basis of the description of the embodiments of the present disclosure, all other embodiments obtained by those skilled in the art without creative work shall fall within the scope of protection of the present disclosure.

Unless otherwise defined, all terms used herein (including technical and scientific terms) have the same meanings as those commonly understood by those skilled in the art that the subject of the present disclosure belongs. Further, it is to be understood that terms such as those defined in commonly used dictionaries should be interpreted as having the meanings consistent with those in the context of the specification and related technologies, and will not be interpreted in an idealized or overly formal form, unless otherwise defined herein. As used herein, the statement that two or more parts are “connected” or “coupled” together shall mean that these parts are combined directly or through one or more intermediate parts.

In all embodiments of the present disclosure, since a source and a drain of a Metal Oxide Semiconductor (MOS) transistor are symmetrical, and on current directions between the sources and the drains of an N-type transistor and a P-type transistor are opposite, in the embodiments of the present disclosure, a controlled middle end of the MOS transistor is referred to as a control electrode, and the remaining two ends of the MOS transistor are referred to as a first electrode and a second electrode, respectively. In addition, for the convenience of unified expression, in the context, a base of a Bipolar Junction Transistor (BJT) is referred to as the control electrode, an emitter of the BJT is referred to as the first electrode, and a collector of the BJT is referred to as the second electrode. In addition, terms such as “first” and “second” are only used for distinguishing one component (or one part of a component) from another component (or another part of a component).

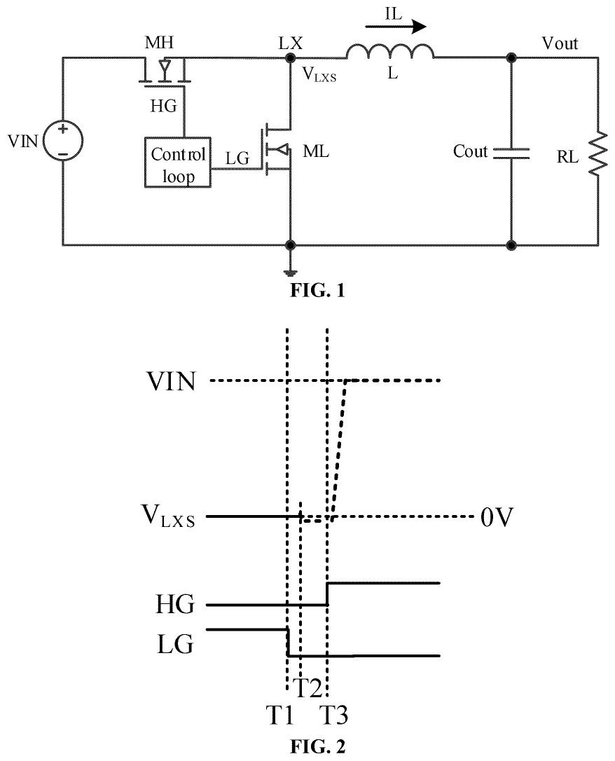

FIG. 1 shows an exemplary topological diagram of a DC-DC converter (synchronous BUCK). In an example of FIG. 1, the DC-DC converter generates an output voltage Vout according to an input voltage VIN. A control loop in the DC-DC converter can generate an upper tube control signal HG and a lower tube control signal LG to control a power transistor MH and a freewheeling tube ML to be alternately turned on. A first end (node LX) of an inductor L is directly coupled to the power transistor MH and the freewheeling tube ML, and a second end of the inductor L is directly coupled to an output energy storage capacitor Cout and an output voltage end Vout. A load resistor RL is also shown in FIG. 1. Under normal conditions, an inductive current IL flows from the first end of the inductor L to the second end. Under light load conditions, when a load current drops below the inductive current IL, a reverse inductive current IL may be present (i.e., the inductive current IL flows from the second end of the inductor L to the first end).

FIG. 2 shows a waveform diagram of a voltage V_{LXS} at a node LX in the absence of a reverse inductive current in a DC-DC converter. At time T1, the lower tube control signal LG is inverted to a low level to control the freewheeling tube ML to turn off, and the inductive current IL freewheels through a body diode of the freewheeling tube ML. After an on delay of the inductor L, at time T2, the voltage V_{LXS} at the node LX becomes negative. At time T3, the upper tube control signal HG is inverted to a high level to control the power transistor MH to be turned on. At this time, the voltage V_{LXS} at the node LX begins to gradually rise to the input voltage VIN. A time period between time T1 and time T3 is usually referred to as “dead time”. As can be seen from FIG. 2, if no reverse current is present within the dead time, the voltage V_{LXS} at the node LX is not higher than 0 V.

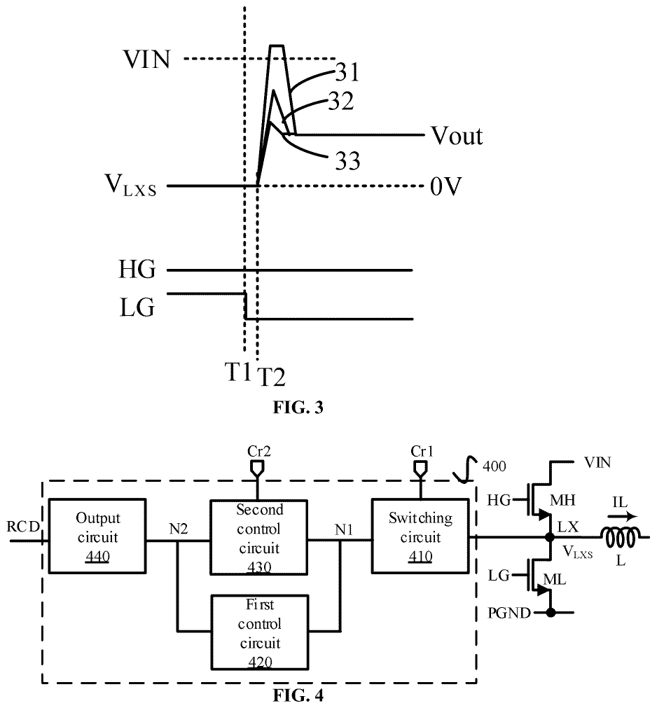

FIG. 3 shows a waveform diagram of a voltage V_{LXS} at a node LX in the presence of a reverse inductive current in a DC-DC converter. Before time T1, if the reverse inductive current IL is present, the voltage V_{LXS} at the node LX may be raised. At this time, the lower tube control signal LG is at the high level, and the freewheeling tube ML is turned on, so that the voltage V_{LXS} at the node LX may rise to a threshold voltage of the freewheeling tube ML. Since the threshold voltage of the freewheeling tube ML is smaller than the input voltage VIN, the slight rise of the voltage V_{LXS} is not visible in FIG. 3. At time T1, the lower tube control signal LG is inverted to the low level to control the freewheeling tube ML to be turned off. After the on delay of the inductor L, at time T2, the voltage V_{LXS} at the node LX begins to gradually rise. When the reverse inductive current IL is large, the reverse inductive current IL may be discharged to the input voltage end VIN through the body diode of the power transistor MH, so that the voltage V_{LXS} at the node LX rises to exceed the input voltage VIN. In this case, a waveform of the voltage V_{LXS} is as shown in a curve 31. If the reverse inductive current IL is small, only the overshoot caused by the reverse inductive current IL charging a parasitic capacitance at the node LX is shown. In this case, the waveform of the voltage V_{LXS} is as shown in a curve 32 or a curve 33. The curve 32 and the curve 33 are configured to represent different overshoot amplitudes.

In this context, the voltage V_{LXS} exceeding 0 V may be referred to as a flyback-surging voltage.

Inductive current zero-crossing detection circuits in the related art mostly detect whether the inductive current is zero-crossing, and do not consider the adaptive adjustment of a zero-crossing detection threshold, so that the uncertainty of the flyback-surging voltage at the node LX is very large. If the inductive current zero-crossing detection circuit in the related art is used, the DC-DC converter may disconnect the freewheeling tube due to the detection of the reverse current, or may trigger the freewheeling of the freewheeling tube within the dead time, resulting in poor disconnection response of the freewheeling tube, and may also first disconnect the freewheeling tube before turning on the power transistor due to the transition from freewheeling to charging on. To this end, the present disclosure provides an inductive current detection circuit for a DC-DC converter, which uses the magnitude of the flyback-surging voltage that may occur when the freewheeling tube is disconnected to evaluate whether a reverse inductive current is present when the freewheeling tube is turned off, and uses the flyback-surging voltage within the dead time to adaptively adjust the current detection threshold, so that the current detection threshold finally converges to a target value. The target value may be zero current or a target reverse current (negative current). Accordingly, the flyback-surging voltage may also converge to a target voltage value. The converged stable flyback-surging voltage may improve the disconnection response of the freewheeling tube (meaning that when the reverse current exists, the freewheeling of the freewheeling tube is not triggered within the dead time). If the current detection threshold finally converges to a negative value, the converged flyback-surging voltage may reduce a voltage difference that needs to be increased when the power transistor is turned on after charging the parasitic capacitance at the node LX, thereby being more conducive to the stability of the output voltage.

FIG. 4 shows a schematic block diagram of an inductive current detection circuit 400 for a DC-DC converter according to an embodiment of the present disclosure. In some embodiments of the present disclosure, the DC-DC converter operates in a DCM. An example of FIG. 4 shows a power transistor MH, a freewheeling tube ML, and an inductor L in the DC-DC converter. An input end of the inductive current detection circuit 400 is coupled to a node LX of the DC-DC converter. The inductive current detection circuit 400 includes a switching circuit 410, a first control circuit 420, a second control circuit 430, and an output circuit 440.

A first end of the switching circuit 410 is directly coupled to a first end of an inductor of the inductor L and a second electrode of the freewheeling tube ML. A second end of the switching circuit 410 is coupled to a first end of the first control circuit 420 and a first end of the second control circuit 430 through a first node N1. The switching circuit 410 is configured to transfer a voltage V_{LXS} at the first end of the inductor L of the DC-DC converter to the first node N1 during the period when a first control signal Cr1 is at an active level. The first end of the inductor L is directly coupled to the second electrode of the freewheeling tube ML of the DC-DC converter. The first control signal Cr1 is at the active level during the freewheeling period when the freewheeling tube ML is turned on and within the dead time immediately after the freewheeling period.

In some embodiments of the present disclosure, the first control signal Cr1 may be generated according to an upper tube control signal HG and a lower tube control signal LG. The first control signal Cr1 is at the active level within a time period from when the lower tube control signal LG is inverted to the active level to when the upper tube control signal HG is inverted to the active level. The inductive current detection circuit 400 may further include a circuit for generating the first control signal Cr1.

The first end of the first control circuit 420 is coupled to the second end of the switching circuit 410 and the first end of the second control circuit 430 through the first node N1. A second end of the first control circuit 420 is coupled to an input end of the output circuit 440 and a second end of the second control circuit 430 through a second node N2. The first control circuit 420 is configured to generate a voltage difference equal to a first increment value between the second node N2 and the first node N1. When the first node N1 is not suspended (i.e., when the first control signal Cr1 is at the active level), the first increment value is greater than 0 V.

The first end of the second control circuit 430 is coupled to the second end of the switching circuit 410 and the first end of the first control circuit 420 through the first node N1. The second end of the second control circuit 430 is coupled to the input end of the output circuit 440 and the second end of the first control circuit 420 through the second node N2. The second control circuit 430 is configured to record a historical voltage positively correlated with a voltage of the first node N1 during the period when a second control signal Cr2 is at the active level, and generate a voltage difference equal to a second increment value between the second node N2 and the first node N1 according to the historical voltage, so that the voltage difference between the second node N2 and the first node N1 is equal to the sum of the first increment value and the second increment value. The second control signal Cr2 is at the active level within the dead time. Therefore, the second control circuit 430 may record the relevant voltage information of the voltage of the node LX within the dead time. In some embodiments of the present disclosure, when the historical voltage is greater than 0 V, the second increment value is greater than 0 V. When the historical voltage is equal to or less than 0 V, the second increment value is equal to 0 V.

In some embodiments of the present disclosure, the second control signal Cr2 may be generated according to the upper tube control signal HG and the lower tube control signal LG. The second control signal Cr2 is at the active level within a time period from when the lower tube control signal LG is inverted to an inactive level to when the upper tube control signal HG is inverted to the active level. The inductive current detection circuit 400 may further include a circuit for generating the second control signal Cr2.

The input end of the output circuit 440 is coupled to the second end of the first control circuit 420 and the second end of the second control circuit 430 through the second node N2. An output end of the output circuit 440 serves as a signal output end of the inductive current detection circuit 400. The output circuit 440 is configured to generate a reverse current detection signal RCD according to a voltage of the second node and output the reverse current detection signal RCD from the signal output end of the inductive current detection circuit 400. The reverse current detection signal RCD is at the inactive level when the voltage of the second node N2 is lower than an inversion threshold. When the voltage of the second node N2 rises to the inversion threshold, the reverse current detection signal RCD is inverted to the active level for turning off the freewheeling tube ML. In practical applications, the inversion threshold is a fixed voltage value that may be set according to a target flyback-surging voltage, the first increment value, and the second increment value. The target flyback-surging voltage is the voltage V_{LXS} at the first end of the inductor L when the inductive current flowing through the inductor L is equal to a target reverse current during the freewheeling period when the freewheeling tube ML is turned on. Here, the second increment value for setting the inversion threshold is positively correlated with the flyback-surging voltage of one cycle before the target flyback-surging voltage is present. In this context, “cycle” refers to a switching cycle of the DC-DC converter.

When no reverse inductive current IL is present in the DC-DC converter using the inductive current detection circuit 400 (the flow direction of the inductive current IL is consistent with the direction indicated by the arrow in FIG. 4), the lower tube control signal LG controls the freewheeling tube ML to be turned on and off according to a preset duty ratio under the control of a Pulse Width Modulation (PWM) signal (not shown).

Assuming that in the n-th cycle, the reverse inductive current IL is present in the DC-DC converter using the inductive current detection circuit 400 (the flow direction of the inductive current IL is opposite to the direction indicated by the arrow in FIG. 4). Then, when the freewheeling tube ML is turned on, the voltage V_{LXS} at the node LX rises slightly (does not exceed the threshold voltage of the freewheeling tube ML). The switching circuit 410 transfers the voltage V_{LXS} to the first node N1. The first control circuit 420 may generate the voltage difference equal to the first increment value between the second node N2 and the first node N1. If the historical voltage previously recorded by the second control circuit 430 is not large enough (for example, the flyback-surging voltage in the previous cycle (the n−1-th cycle) is small, or no flyback-surging voltage is present), the voltage difference equal to the second increment value generated by the second control circuit 430 between the second node N2 and the first node N1 is small (or zero). Since the voltage difference between the second node N2 and the first node N1 is equal to the sum of the first increment value and the second increment value, the flyback-surging voltage V_{LXS} at the node LX cannot push the voltage of the second node N2 to exceed the inversion threshold, so that the reverse current detection signal RCD cannot be inverted to the active level. Referring to FIG. 3, after the freewheeling tube ML is disconnected, the rise amplitude of the flyback-surging voltage V_{LXS} may be significantly increased. At this time, the flyback-surging voltage V_{LXS} may be provided to the second control circuit 430 through the first node N1 and converted into the historical voltage by the second control circuit 430. The historical voltage is recorded in the second control circuit 430 for use in the next cycle (the n+1-th cycle).

In the next cycle (the n+1-th cycle), if the reverse inductive current IL is still present, since the historical voltage is large, the second increment value is also large, and the flyback-surging voltage V_{LXS} may push the voltage of the second node N2 to exceed the inversion threshold without rising to a value of the previous cycle (the n-th cycle). At this time, the reverse current detection signal RCD is inverted to the active level, so that the lower tube control signal LG is inverted to the inactive level in advance, thereby turning off the freewheeling tube ML in advance. In this way, the reverse inductive current IL of the next cycle (the n+2-th cycle) may be reduced accordingly, thereby reducing the flyback-surging voltage V_{LXS}. By setting a transfer coefficient (a ratio of the historical voltage to the flyback-surging voltage V_{LXS}) between the flyback-surging voltage V_{LXS} within the dead time and the historical voltage recorded by the second control circuit 430, the reverse inductive current IL may gradually converge, and the flyback-surging voltage V_{LXS} may also gradually converge, and finally reach stability. Here, the transfer coefficient should be set to be less than 1. In addition, by setting the inversion threshold, the flyback-surging voltage V_{LXS} may finally converge to the target flyback-surging voltage, so that the reverse inductive current IL finally converges to the target reverse current. The target flyback-surging voltage and the target reverse current may be determined according to actual applications.

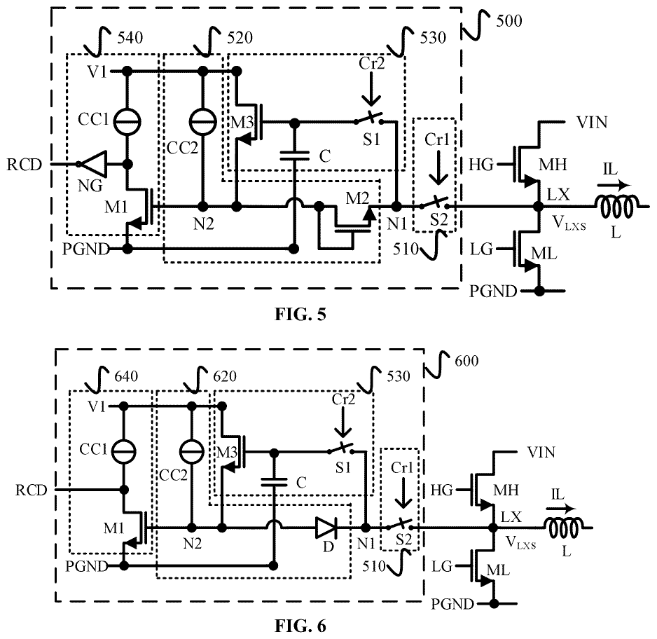

FIG. 5 shows an exemplary circuit diagram of an inductive current detection circuit 500 for a DC-DC converter according to an embodiment of the present disclosure. In an example of FIG. 5, an active level of a reverse current detection signal RCD is a high level. The output circuit 540 may include a first constant current source CC1, a first transistor M1, and an inverter NG. The first constant current source CC1 may be powered by a first voltage V1 from a first voltage end V1. The first constant current source CC1 is configured to output a first constant current CC1. A control electrode of the first transistor M1 is coupled to a second node N2. A first electrode of the first transistor M1 is coupled to a first electrode of a freewheeling tube ML. A second electrode of the first transistor M1 is coupled to an output end of the first constant current source CC1 and an input end of the inverter NG. An output end of the inverter NG is coupled to a signal output end.

In the example of FIG. 5, the first control circuit 520 includes a second constant current source CC2 and a second transistor M2. The second constant current source CC2 may be powered by the first voltage V1. The second constant current source CC2 is configured to output a second constant current CC2. The second constant current CC2 is less than the first constant current CC1. A control electrode and a second electrode of the second transistor M2 are coupled to the second node N2 and an output end of the second constant current source CC2. A first electrode of the second transistor M2 is coupled to a first node N1.

In some embodiments of the present disclosure, the size of the second transistor M2 is the same as that of the first transistor M1.

In the example of FIG. 5, the second control circuit 530 includes a first switch S1, a third transistor M3, and a capacitor C. A controlled end of the first switch S1 is provided with a second control signal Cr2. A first end of the first switch S1 is coupled to the first node N1. A second end of the first switch S1 is coupled to a first end of the capacitor C and a control electrode of the third transistor M3. A second end of the capacitor C is coupled to the first electrode of the first transistor M1. A first electrode of the third transistor M3 is coupled to the second node N2. A second electrode of the third transistor M3 is coupled to the first voltage end V1.

In some embodiments of the present disclosure, the first switch S1 may be implemented by the transistor. For convenience of reference, the transistor is referred to as a fourth transistor. A control electrode of the fourth transistor is provided with the second control signal Cr2. A first electrode of the fourth transistor is coupled to the first end of the capacitor C and the control electrode of the third transistor M3. A second electrode of the fourth transistor is coupled to the first node N1. A transfer coefficient between a flyback-surging voltage VLXS within the dead time and a historical voltage recorded by the second control circuit 430 may be set by the internal resistance of the fourth transistor.

In the example of FIG. 5, the switching circuit 510 includes a second switch S2. A controlled end of the second switch S2 is provided with the first control signal Cr1. A first end of the second switch S2 is coupled to the first node N1. A second end of the second switch S2 is directly coupled to a first end of an inductor L of the DC-DC converter and a second electrode (i.e., node LX) of the freewheeling tube ML.

FIG. 6 shows an exemplary circuit diagram of an inductive current detection circuit 600 for a DC-DC converter according to an embodiment of the present disclosure. An output circuit 640 and a first control circuit 620 in FIG. 6 are variations of the output circuit 540 and the first control circuit 520 in FIG. 5. In an example of FIG. 6, an active level of a reverse current detection signal RCD is a low level. The output circuit 640 includes a first constant current source CC1 and a first transistor M1. The first constant current source CC1 may be powered by a first voltage V1 from a first voltage end V1. The first constant current source CC1 is configured to output a first constant current CC1. A control electrode of the first transistor M1 is coupled to a second node N2. A first electrode of the first transistor M1 is coupled to a first electrode of a freewheeling tube ML. A second electrode of the first transistor M1 is coupled to an output end of the first constant current source CC1 and a signal output end.

In the example of FIG. 6, the first control circuit 620 includes a second constant current source CC2 and a diode D. The second constant current source CC2 may be powered by the first voltage V1. The second constant current source CC2 is configured to output a second constant current CC2. The second constant current CC2 is less than the first constant current CC1. An anode of the diode D is coupled to the second node N2 and an output end of the second constant current source CC2. A cathode of the diode D is coupled to a first node N1.

In some embodiments of the present disclosure, a threshold voltage of the diode D is equal to a threshold voltage of the first transistor M1.

In the examples of FIG. 5 and FIG. 6, a high voltage signal is input from the first voltage end V1, and a second voltage end V2 is grounded. The first voltage end V1 may also be an input voltage end VIN. The first transistor MI to a third transistor M3 are N-channel Metal Oxide Semiconductor (NMOS) transistors. It should be understood by those skilled in the art that variations of the circuit shown in FIG. 5 and FIG. 6 based on the above-mentioned inventive concept should also fall within the scope of protection of the present disclosure. In this variation, the above-mentioned transistors and the voltage ends may also have different settings from the example shown in FIG. 5 and FIG. 6.

A working process of the inductive current detection circuit 500 according to the embodiment of the present disclosure is explained below with reference to the example of FIG. 5. When no reverse inductive current IL is present in the DC-DC converter using the inductive current detection circuit 500 (the flow direction of the inductive current IL is consistent with the direction indicated by the arrow in FIG. 5), the lower tube control signal LG controls the freewheeling tube ML to be turned on and off according to a preset duty ratio under the control of a PWM signal (not shown).

Assuming that in the n-th cycle, the reverse inductive current IL is present in the DC-DC converter using the inductive current detection circuit 500 (the flow direction of the inductive current IL is opposite to the direction indicated by the arrow in FIG. 5). Then, when the freewheeling tube ML is turned on, the voltage V_{LXS} at the node LX rises slightly (does not exceed the threshold voltage of the freewheeling tube ML). At this time, the first control signal Cr1 is at the active level, and the second switch is closed, thereby transferring the voltage V_{LXS} to the first node N1. Through the second constant current source CC2, the second transistor M2 is turned on, thereby generating the voltage difference equal to the first increment value (equal to the threshold voltage of the second transistor M2) between the second node N2 and the first node N1. If the flyback-surging voltage is small in the previous cycle (the n−1-th cycle), or no flyback-surging voltage is present, the charge stored on the capacitor C is not enough (the historical voltage is not large enough), the third transistor M3 is not fully turned on or is in a cut-off state (the second increment value is small or zero). Since the voltage difference between the second node N2 and the first node N1 is equal to the sum of the first increment value and the second increment value, the flyback-surging voltage V_{LXS} at the node LX cannot push the voltage of the second node N2 to exceed the inversion threshold, so that the reverse current detection signal RCD may not be inverted to the active level. From the perspective of the current, if the voltage V_{LXS} at the node LX is zero, since the first transistor M1 and the second transistor M2 have the same size, the current flowing through the first transistor M1 is equal to the current (the second constant current CC2) flowing through the second transistor M2. Therefore, if the reverse inductive current IL is not higher than the difference between the first constant current CC1 and the second constant current CC2, the reverse current detection signal RCD cannot be inverted to the active level.

Referring to FIG. 3, after the freewheeling tube ML is disconnected, the rise amplitude of the flyback-surging voltage V_{LXS} may be significantly increased. At this time, the flyback-surging voltage V_{LXS} may be provided to the first switch S1 through the first node N1. Due to the internal resistance of the first switch S1, the flyback-surging voltage V_{LXS} is stored at the first end of the capacitor C after being multiplied by the transfer coefficient for use in the next cycle (the n+1-th cycle). At this time, since the freewheeling tube ML has been disconnected, even if the reverse current detection signal RCD is inverted to the active level, the normal operation of the DC-DC converter is not affected.

In the next cycle (the n+1-th cycle), if the reverse inductive current IL is still present, since the voltage (historical voltage) of the first end of the capacitor C is large, the voltage of the second node N2 is pulled up accordingly (the second increment value is the historical voltage minus a gate-source voltage of the third transistor), and the flyback-surging voltage V_{LXS} may push the voltage of the second node N2 to exceed the inversion threshold without rising to the value of the previous cycle (the n-th cycle). At this time, the reverse current detection signal RCD is inverted to the active level, so that the lower tube control signal LG is inverted to the inactive level in advance, thereby turning off the freewheeling tube ML in advance. In this way, the reverse inductive current IL of the next cycle (the n+2-th cycle) may be reduced accordingly, thereby reducing the flyback-surging voltage V_{LXS}. By reasonably setting an internal resistance value of the first switch S1, the reverse inductive current IL may gradually converge, and the flyback-surging voltage V_{LXS} may also gradually converge, and finally reach stability. Here, the internal resistance value of the first switch S1 is set, so that the transfer coefficient is less than 1. In addition, by setting the inversion threshold, the flyback-surging voltage V_{LXS} may finally converge to the target flyback-surging voltage, thereby making the reverse inductive current IL finally converge to the target reverse current. The target flyback-surging voltage and the target reverse current may be determined according to actual applications.

The operating process of the inductive current detection circuit 600 in FIG. 6 is similar to the operating process of the inductive current detection circuit 500 in FIG. 5, which will not be elaborated herein. It is to be noted that in FIG. 6, the voltage difference of the first increment value may also be generated between the second node N2 and the first node N1 by using the diode D, so that the diode D in FIG. 6 may be configured to replace the second transistor M2 in FIG. 5.

The embodiments of the present disclosure further provide a chip. The chip includes a DC-DC converter according to an embodiment of the present disclosure. The chip is, for example, a power management chip.

The embodiments of the present disclosure further provide an electronic device. The electronic device includes a chip according to an embodiment of the present disclosure. The electronic device is, for example, an intelligent terminal device, such as a tablet computer, a smart phone, etc.

In summary, in the inductive current detection circuit for the DC-DC converter according to the embodiment of the present disclosure, the detection threshold of the inductive current is adaptively adjusted by using the flyback-surging voltage within the dead time, so that the inductive current value when the reverse current detection signal is inverted to the active level gradually converges and finally reaches stability, and the flyback-surging voltage may also gradually converge and finally reach stability. The converged stable flyback-surging voltage may improve the disconnection response of the freewheeling tube (meaning that when a reverse current exists, the freewheeling of the freewheeling tube is not triggered within the dead time). If the current detection threshold finally converges to a negative value, the converged flyback-surging voltage may reduce a voltage difference that needs to be increased when the power transistor is turned on after charging the parasitic capacitance at the node LX, thereby being more conducive to the stability of the output voltage. Accordingly, the DC-DC converter using the inductive current detection circuit according to the embodiment of the present disclosure also has the above advantages.

Unless otherwise indicated clearly in the context, the singular form of the present disclosure used herein and in the appended claims includes the plural, and vice versa. Therefore, when referring to the singular, it usually includes the plural of the corresponding term. Similarly, the words “include” and “comprise” will be interpreted as inclusive rather than exclusive. Similarly, the terms “include” and “or” shall be interpreted as including, unless such interpretation is expressly prohibited in the present disclosure. Where the term “example” is used in the present disclosure, particularly when it is behind a group of terms, the “example” is only exemplary and illustrative, and should not be considered exclusive or extensive.

Further aspects and scope of adaptability become apparent from the description provided by the present disclosure. It is to be understood that various aspects of the present disclosure may be implemented separately or in combination with one or more other aspects. It is also to be understood that the description and specific embodiments in the present disclosure are for illustrative purposes only and are not intended to limit the scope of the present disclosure.

Several embodiments of the present disclosure have been described in detail above. However, apparently, those skilled in the art can make various modifications and variants to the embodiments of the present disclosure without departing from the spirit and scope of the present disclosure. The scope of the present disclosure is limited by the appended claims.

What is claimed is:

1. An inductive current detection circuit for a Direct Current (DC)-DC converter, comprising a switching circuit, a first control circuit, a second control circuit, and an output circuit;
wherein the switching circuit is configured to transfer a voltage at a first end of an inductor of the DC-DC converter to a first node during a the period when a first control signal is at an active level, a first end of the inductor is directly coupled to a second electrode of a freewheeling tube of the DC-DC converter, and the first control signal is at the active level during a freewheeling period when the freewheeling tube is turned on and within dead time immediately after the freewheeling period;
the first control circuit is configured to generate a voltage difference equal to a first increment value between the second node and the first node;
the second control circuit is configured to record a historical voltage positively correlated with a voltage of the first node during a the period when the second control signal is at the active level, and generate a voltage difference equal to a second increment value between the second node and the first node according to the historical voltage, wherein the voltage difference between the second node and the first node is equal to a sum of the first increment value and the second increment value, and the second control signal is at the active level during the dead time; and
the output circuit is configured to generate a reverse current detection signal according to a voltage of the second node and output the reverse current detection signal from a signal output end of the inductive current detection circuit, and when the voltage of the second node rises to an inversion threshold, the reverse current detection signal is inverted to the active level for turning off the freewheeling tube.

2. The inductive current detection circuit according to claim 1, wherein the active level of the reverse current detection signal is a high level, and the output circuit comprises a first constant current source, a first transistor, and an inverter;
wherein the first constant current source is configured to output a first constant current;
a control electrode of the first transistor is coupled to the second node, a first electrode of the first transistor is coupled to a first electrode of the freewheeling tube, and a second electrode of the first transistor is coupled to an output end of the first constant current source and an input end of the inverter; and
an output end of the inverter is coupled to the signal output end.

3. The inductive current detection circuit according to claim 1, wherein the active level of the reverse current detection signal is a low level, and the output circuit comprises a first constant current source and a first transistor;
wherein the first constant current source is configured to output a first constant current; and
a control electrode of the first transistor is coupled to the second node, a first electrode of the first transistor is coupled to a first electrode of the freewheeling tube, and a second electrode of the first transistor is coupled to an output end of the first constant current source and the signal output end.

4. The inductive current detection circuit according to claim 2, wherein the first control circuit comprises a second constant current source and a second transistor;
wherein the second constant current source is configured to output a second constant current, and the second constant current is less than the first constant current; and
a control electrode and a second electrode of the second transistor are coupled to the second node and an output end of the second constant current source, and a first electrode of the second transistor is coupled to the first node.

5. The inductive current detection circuit according to claim 4, wherein a size of the second transistor is the same as a size of the first transistor.

6. The inductive current detection circuit according to claim 2, wherein the first control circuit comprises a second constant current source and a diode;
wherein the second constant current source is configured to output a second constant current, and the second constant current is less than the first constant current; and
an anode of the diode is coupled to the second node and an output end of the second constant current source, and a cathode of the diode is coupled to the first node.

7. The inductive current detection circuit according to claim 6, wherein a threshold voltage of the diode is equal to a threshold voltage of the first transistor.

8. The inductive current detection circuit according to claim 2, wherein the second control circuit comprises a first switch, a third transistor, and a capacitor;
wherein a controlled end of the first switch is provided with the second control signal, a first end of the first switch is coupled to the first node, and a second end of the first switch is coupled to a first end of the capacitor and a control electrode of the third transistor;
a second end of the capacitor is coupled to the first electrode of the first transistor; and
a first electrode of the third transistor is coupled to the second node, and a second electrode of the third transistor is coupled to a first voltage end.

9. The inductive current detection circuit according to claim 8, wherein the first switch is a fourth transistor; and
a control electrode of the fourth transistor is provided with the second control signal, a first electrode of the fourth transistor is coupled to the first end of the capacitor and the control electrode of the third transistor, and a second electrode of the fourth transistor is coupled to the first node.

10. The inductive current detection circuit according to claim 1, wherein the switching circuit comprises a second switch;
a controlled end of the second switch is provided with the first control signal, a first end of the second switch is coupled to the first node, and a second end of the second switch is coupled to the first end of the inductor of the DC-DC converter and the second electrode of the freewheeling tube.

11. The inductive current detection circuit according to claim 1, wherein the DC-DC converter operates in a Discontinuous Conduction Mode (DCM).

12. The inductive current detection circuit according to claim 1, wherein a first end of the switching circuit is coupled to the first end of the inductor and the second electrode of the freewheeling tube, and a second end of the switching circuit is coupled to a first end of the first control circuit and a first end of the second control circuit through the first node;
a second end of the first control circuit is coupled to an input end of the output circuit and a second end of the second control circuit through the second node; and
an output end of the output circuit serves as the signal output end of the inductive current detection circuit.

13. The inductive current detection circuit according to claim 1, wherein the first control signal is generated according to an upper tube control signal and a lower tube control signal, and the first control signal is at the active level within a time period from when the lower tube control signal is inverted to the active level to when the upper tube control signal is inverted to the active level.

14. The inductive current detection circuit according to claim 1, wherein the second control signal is generated according to an upper tube control signal and a lower tube control signal, and the second control signal is at the active level within a time period from when the lower tube control signal is inverted to an inactive level to when the upper tube control signal is inverted to the active level.

15. An inductive current detection circuit for a DC-DC converter, comprising a first transistor, a second transistor, a third transistor, a first constant current source, a second constant current source, a capacitor, a first switch, a second switch, and an inverter;
wherein the first constant current source is configured to output a first constant current;
a control electrode of the first transistor is coupled to a control electrode and a second electrode of the second transistor, a first electrode of the first transistor is coupled to a first electrode of a freewheeling tube of the DC-DC converter, and a second electrode of the first transistor is coupled to an output end of the first constant current source and an input end of the inverter;
an output end of the inverter is coupled to a signal output end of the inductive current detection circuit, a reverse current detection signal is output from the signal output end, and an active level of the reverse current detection signal is configured to turn off the freewheeling tube;
the second constant current source is configured to output a second constant current, and the second constant current is less than the first constant current;
the control electrode of the second transistor is coupled to an output end of the second constant current source and a first electrode of the third transistor, and a first electrode of the second transistor is coupled to a first end of the first switch and a first end of the second switch;
a controlled end of the second switch is provided with a first control signal, a second end of the second switch is coupled to a first end of an inductor of the DC-DC converter and a second electrode of the freewheeling tube, and the first control signal is at the active level during a the freewheeling period when the freewheeling tube is turned on and within the dead time immediately after the freewheeling period;
a controlled end of the first switch is provided with a second control signal, a second end of the first switch is coupled to a first end of the capacitor and a control electrode of the third transistor, and the second control signal is at the active level within the dead time;
a second end of the capacitor is coupled to the first electrode of the first transistor; and
a second electrode of the third transistor is coupled to a first voltage end.

16. A DC-DC converter, comprising the inductive current detection circuit according to claim 1,

17. A chip, comprising the DC-DC converter according to claim 16.

18. An electronic device, comprising the chip according to claim 17.
